(19) United States
(12) Patent Application Publication
(10) Pub. No.: US 2018/0211974 A1
(43) Pub. Date: Jul. 26, 2018

(54) DISPLAY PANEL AND DISPLAY DEVICE

(71) Applicant: SHENZHEN CHINA STAR OPTOELECTRONICE TECHNOLOGY CO. LTD, Shenzhen, Guangdong (CN)

(72) Inventors: Yuyeh CHEN, Shenzhen, Guangdong (CN); Jhenwei HE, Shenzhen, Guangdong (CN); Anle HU, Shenzhen, Guangdong (CN)

(21) Appl. No.: 15/327,543

(22) PCT Filed: Dec. 28, 2016
(86) PCT No.: PCT/CN2016/112538

§ 371 Date: Jan. 19, 2017

(30) Foreign Application Priority Data
Nov. 8, 2016 (CN) 201610979659.5

(51) Int. Cl. H01L 27/12; G02F 1/1362; G09G 3/20

(52) U.S. Cl. CPC H01L 27/124; G09G 2310/0283; G09G 3/20; G02F 1/136286

(57) ABSTRACT

The present disclosure provides a display panel which includes a display panel body, a first data line driving circuit and a second data line driving circuit positioned at two sides of the display panel body, first pixel units driven by the first data line driving circuit, and second pixel units driven by the second data line driving circuit. A dividing line is formed between the first pixel units and the second pixel units, and the dividing line is a non-straight line.

### BACKGROUND OF THE INVENTION

### Field of Invention

The present disclosure relates to a display driving field, and more particularly to a display panel and a display device.

### Description of Prior Art

With the development of the TFT technology, display effect of liquid crystal display panels on the market is demanding higher and higher. High-resolution and large-sized products are gradually favored by the market. A resolution is developed from 1920*1080 to 3840*2160, 4k, 8K, and even 10K in the future. A size is from 32 inches, 40 inches, 55 inches, 110 inches, and so on.

A large-sized and high-resolution display panel usually has a structure as shown in FIG. 1 and includes a first data line driving circuit 11, a second data line driving circuit 12, a first scan line driving circuit 13, a second scan line driving circuit 14, and pixel units. The pixel units are positioned in a first area 15, a second area 16, a third area 17, and a fourth area 18. The first data line driving circuit 11 and the first scan line driving circuit 13 are responsible for display driving of the pixel units in the first area 15. The first data line driving circuit 11 and the second scan line driving circuit 14 are responsible for display driving of the pixel units in the second area 16. The second data line driving circuit 12 and the first scan line driving circuit 13 are responsible for display driving of the pixel units in the third area 17. The second data line driving circuit 12 and the second scan line driving circuit 14 are responsible for display driving of the pixel units in the fourth area 18. This split-screen display method can ensure that the display panel has a high resolution and a high refresh rate.

However, since data lines driven by the first data line driving circuit 11 and data lines driven by the second data line driving circuit 12 have wiring differences (e.g., differences of wiring lengths or differences of wiring resistance values), a display difference line (a dark line) exists in a border between the first area 15 and the third area 17 and in a border between the second area 16 and the fourth area 18 due to different display effects. Accordingly, display effect of the liquid crystal display panel is affected.

Consequently, there is a need to provide a display panel and a display device to solve the problem in the prior art.

### SUMMARY OF THE INVENTION

An objective of the present disclosure is to provide a display panel and a display device capable of increasing display effect of the display panel and solving the problem that display effect is worse in a conventional display panel and a conventional display device.

An embodiment of the present disclosure provides a display panel which comprises a display panel body, a first data line driving circuit and a second data line driving circuit positioned at two sides of the display panel body, first pixel units driven by the first data line driving circuit, and second pixel units driven by the second data line driving circuit.

A dividing line is formed between the first pixel units and the second pixel units, and the dividing line is a non-straight line.

The dividing line includes at least one of a dividing line in a wave shape, a dividing line in a square wave shape, a dividing line in a sine wave shape, a dividing line in a triangle wave shape, a dividing line in a trapezoid wave shape, and a dividing line in a step wave shape. The dividing line swings at two sides of a horizontal center line of the display panel.

An embodiment of the present disclosure further provides a display panel which comprises a display panel body, a first data line driving circuit and a second data line driving circuit positioned at two sides of the display panel body, first pixel units driven by the first data line driving circuit, and second pixel units driven by the second data line driving circuit.

A dividing line is formed between the first pixel units and the second pixel units, and the dividing line is a non-straight line.

In the display panel of the present disclosure, the dividing line is a dividing line in a wave shape, and the dividing line swings at two sides of a horizontal center line of the display panel.

In the display panel of the present disclosure, the dividing line is a dividing line in a square wave shape.

In the display panel of the present disclosure, a highest point and a lowest point of the dividing line in the square wave shape are respectively set at two sides of the horizontal center line of the display panel.

In the display panel of the present disclosure, a distance between the highest point of the dividing line in the square wave and the horizontal center line is approximately equal to a distance between the lowest point of the dividing line in the square wave and the horizontal center line.

In the display panel of the present disclosure, the dividing line is a dividing line in a sine wave shape.

In the display panel of the present disclosure, a highest point and a lowest point of the dividing line in the square wave shape are respectively set at the two sides of the horizontal center line of the display panel.

In the display panel of the present disclosure, a distance between the highest point of the dividing line in the sine wave and the horizontal center line is approximately equal to a distance between the lowest point of the dividing line in the sine wave and the horizontal center line.

In the display panel of the present disclosure, the dividing line includes at least one of a dividing line in a square wave shape, a dividing line in a sine wave shape, a dividing line in a triangle wave shape, a dividing line in a trapezoid wave shape, and a dividing line in a step wave shape.

The present disclosure further provides a display device which comprises a display panel. The display panel comprises a display panel body, a first data line driving circuit and a second data line driving circuit positioned at two sides of the display panel body, first pixel units driven by the first data line driving circuit, and second pixel units driven by the second data line driving circuit.

A dividing line is formed between the first pixel units and the second pixel units, and the dividing line is a non-straight line.

In the display device of the present disclosure, the dividing line is a dividing line in a wave shape, and the dividing line swings at two sides of a horizontal center line of the display panel.

In the display device of the present disclosure, the dividing line is a dividing line in a square wave shape.

In the display device of the present disclosure, a highest point and a lowest point of the dividing line in the square wave shape are respectively set at two sides of the horizontal center line of the display panel.

In the display device of the present disclosure, a distance between the highest point of the dividing line in the square wave and the horizontal center line is approximately equal to a distance between the lowest point of the dividing line in the square wave and the horizontal center line.

In the display device of the present disclosure, the dividing line is a dividing line in a sine wave shape.

In the display device of the present disclosure, a highest point and a lowest point of the dividing line in the square wave shape are respectively set at the two sides of the horizontal center line of the display panel.

In the display device of the present disclosure, a distance between the highest point of the dividing line in the sine wave and the horizontal center line is approximately equal to a distance between the lowest point of the dividing line in the sine wave and the horizontal center line.

In the display device of the present disclosure, the dividing line includes at least one of a dividing line in a square wave shape, a dividing line in a sine wave shape, a dividing line in a triangle wave shape, a dividing line in a trapezoid wave shape, and a dividing line in a step wave shape.

Compared with the conventional display panel and the conventional display device, the dividing line which is a non-straight line in the display panel and the display device in accordance with the present disclosure is disposed between the first pixel units and the corresponding second pixel units, so as to eliminate the dark phenomenon between the first pixel units and the second pixel units, increase the display effect of the display panel, and solve the technical problem that the display effect is worse in a conventional display panel and a conventional display device.

For a better understanding of the aforementioned content of the present disclosure, preferable embodiments are illustrated in accordance with the attached figures for further explanation.

### BRIEF DESCRIPTION OF THE DRAWINGS

FIG. 1 is a structural diagram of a conventional display panel.

FIG. 2 is a structural diagram of a display panel in accordance with a first preferred embodiment of the present disclosure.

FIG. 3 is a structural diagram of a display panel in accordance with a second preferred embodiment of the present disclosure.

FIG. 4 is a structural diagram of a display panel in accordance with a third preferred embodiment of the present disclosure.

FIG. 5 is a structural diagram of a display panel in accordance with a fourth preferred embodiment of the present disclosure.

FIG. 6 is a structural diagram of a display panel in accordance with a fifth preferred embodiment of the present disclosure.

FIG. 7 is a structural diagram of a display panel in accordance with a sixth preferred embodiment of the present disclosure.

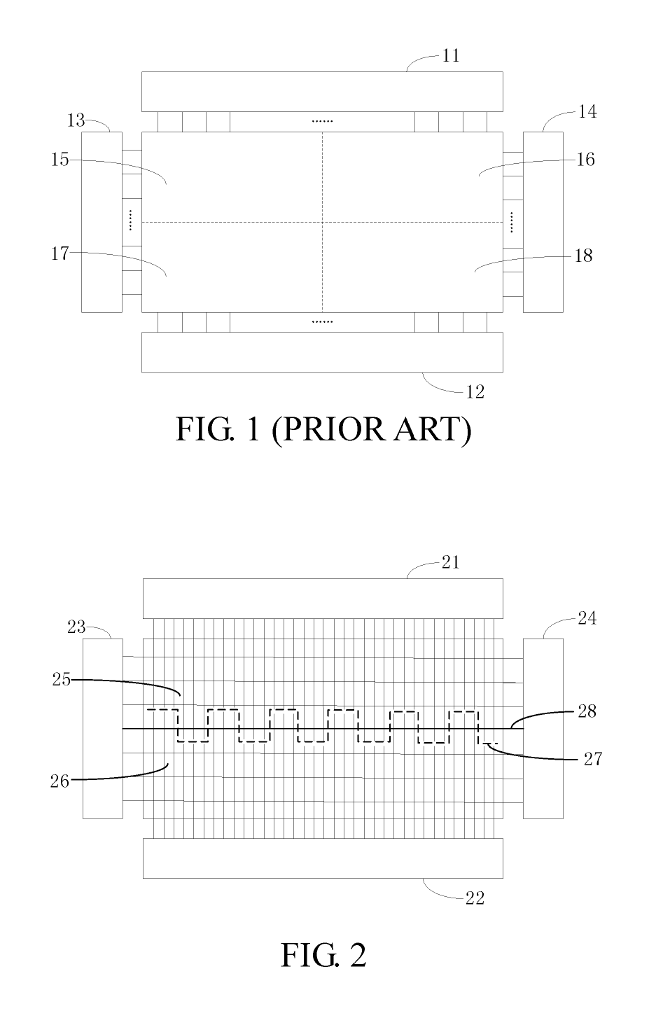

### DETAILED DESCRIPTION OF THE PREFERRED EMBODIMENTS

The following embodiments are referring to the accompanying drawings for exemplifying specific implementable embodiments of the present disclosure. Furthermore, directional terms described by the present disclosure, such as upper, lower, front, back, left, right, inner, outer, side and etc., are only directions by referring to the accompanying drawings, and thus the used directional terms are used to describe and understand the present disclosure, but the present disclosure is not limited thereto.

In the drawings, structure-like elements are labeled with like reference numerals.

Please refer to FIG. 2. FIG. 2 is a structural diagram of a display panel in accordance with a first preferred embodiment of the present disclosure. The display panel in accordance with the present preferred embodiment includes a display panel body, a first data line driving circuit 21 and a second data line driving circuit 22 which are positioned at two sides of the display panel body, a first scan line driving circuit 23 and a second scan line driving circuit 24 which are positioned at the other two sides of the display panel body, first pixel units 25 which are driven by the first data line driving circuit 21, and second pixel units 26 which are driven by the second data line driving circuit 22. A dividing line is formed between the first pixel units 25 and the second pixel units 26. The dividing line is a non-straight line.

In the present preferred embodiment, the dividing line is a dividing line in a wave shape. The dividing line is a dividing line 27 in a square wave shape. The dividing line swings at two sides of a horizontal center line 28 of the display panel.

When the display panel in accordance with the present preferred embodiment is utilized, the first data line driving circuit 21 transmits data signals to the first pixel units 25 under driving of scan signals of the first scan line driving circuit 23 and driving of scan signals of the second scan line driving circuit 24. The second data line driving circuit 22 transmits data signals to the second pixel units 26 under the driving of the scan signals of the first scan line driving circuit 23 and the driving of the scan signals of the second scan line driving circuit 24.

The dividing line 27 in the square wave shape between the first pixel units 25 and the second pixel units 26 is not positioned in a same straight line. The dividing line 27 in the square wave shape swings at the two sides of the horizontal center line 28 of the display panel. Display effect of the firs pixel units 25 and display effect of the second pixel units 26 have a larger difference. However, since a dark line exists at the two sides of the horizontal center line 28, human visual sense of the dark line is significantly weakened and even human eyes cannot perceive the existence of the dark line.

Preferably, in order to decrease a driving difference between the first pixel units 25 and the second pixel units 26, a highest point and a lowest point of the dividing line in the square wave 27 may be respectively set at the two sides of horizontal center line 28 of the display panel. As such, the first data line driving circuit 21 and the second data line driving circuit 22 may be disposed symmetrically.

Preferably, in order to decrease the driving difference between the first pixel units 25 and the second pixel units 26, a distance between the highest point of the dividing line in the square wave 27 and the horizontal center line 28 is approximately equal to a distance between the lowest point of the dividing line in the square wave 27 and the horizontal center line 28. As such, the human visual sense of the dark line is significantly weakened, and even the human eyes cannot perceive the existence of the dark line.

In the display panel in accordance with the present preferred embodiment, the dividing line in the square wave shape is disposed to eliminate the dark phenomenon between the first pixel units and the second pixel units, thereby increasing the display effect of the display panel.

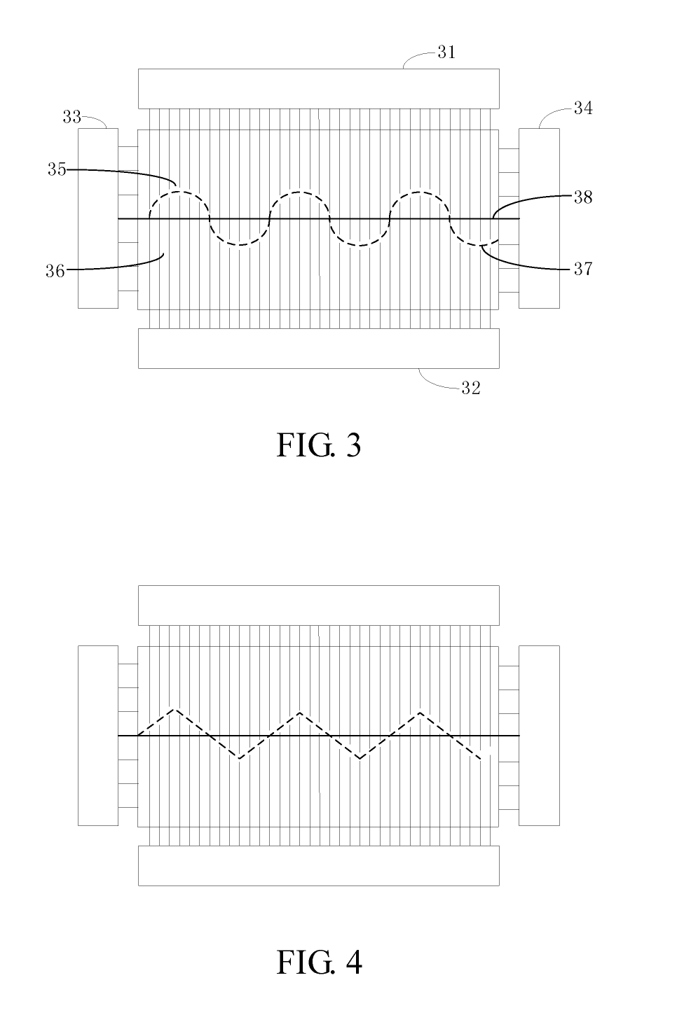

Please refer to FIG. 3. FIG. 3 is a structural diagram of a display panel in accordance with a second preferred embodiment of the present disclosure. The display panel in accordance with the present preferred embodiment includes a display panel body, a first data line driving circuit 31 and a second data line driving circuit 32 which are positioned at two sides of the display panel body, a first scan line driving circuit 33 and a second scan line driving circuit 34 which are positioned at the other two sides of the display panel body, first pixel units 35 which are driven by the first data line driving circuit 31, and second pixel units 36 which are driven by the second data line driving circuit 32. A dividing line is formed between the first pixel units 35 and the second pixel units 36. The dividing line is a non-straight line.

In the present preferred embodiment, the dividing line is a dividing line in a wave shape. The dividing line is a dividing line 27 in a sine wave shape. The dividing line swings at two sides of a horizontal center line 38 of the display panel.

When the display panel in accordance with the present preferred embodiment is utilized, the first data line driving circuit 31 transmits data signals to the first pixel units 35 under driving of scan signals of the first scan line driving circuit 33 and driving of scan signals of the second scan line driving circuit 34. The second data line driving circuit 32 transmits data signals to the second pixel units 36 under the driving of the scan signals of the first scan line driving circuit 33 and the driving of the scan signals of the second scan line driving circuit 34.

The dividing line 37 in the sine wave shape between the first pixel units 35 and the second pixel units 36 is not positioned in a same straight line. The dividing line 37 in the sine wave shape swings at the two sides of the horizontal center line 38 of the display panel. Display effect of the firs pixel units 35 and display effect of the second pixel units 36 have a larger difference. However, since a dark line exists at the two sides of the horizontal center line 38, human visual sense of the dark line is significantly weakened.

Preferably, in order to decrease a driving difference between the first pixel units 35 and the second pixel units 36, a highest point and a lowest point of the dividing line in the sine wave 37 may be respectively set at the two sides of horizontal center line 38 of the display panel. As such, the first data line driving circuit 31 and the second data line driving circuit 32 may be disposed symmetrically.

Preferably, in order to decrease the driving difference between the first pixel units 35 and the second pixel units 36, a distance between the highest point of the dividing line in the square wave 37 and the horizontal center line 38 is approximately equal to a distance between the lowest point of the dividing line in the square wave 37 and the horizontal center line 38, so as to dispose the first data line driving circuit 31 and the second data line driving circuit 32 preferably.

In the display panel in accordance with the present preferred embodiment, the dividing line in the sine wave shape is disposed to eliminate the dark phenomenon between the first pixel units and the second pixel units, thereby increasing the display effect of the display panel.

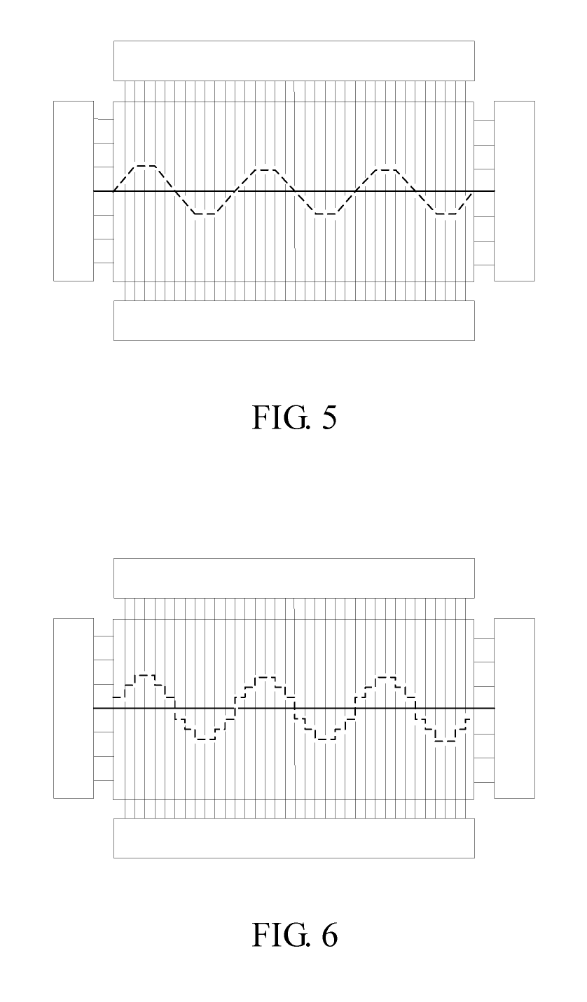

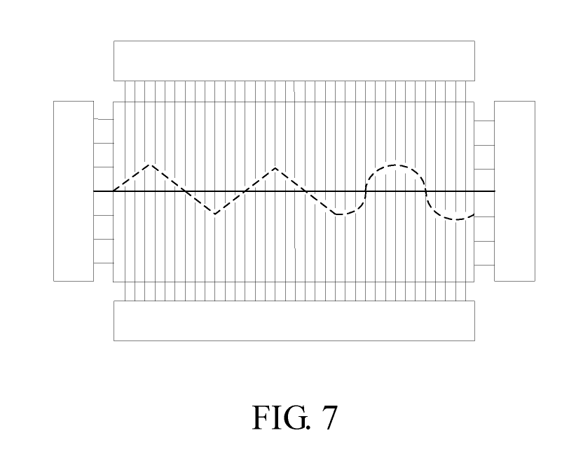

Please refer to FIG. 4 to FIG. 7. FIG. 4 is a structural diagram of a display panel in accordance with a third preferred embodiment of the present disclosure. FIG. 5 is a structural diagram of a display panel in accordance with a fourth preferred embodiment of the present disclosure. FIG. 6 is a structural diagram of a display panel in accordance with a fifth preferred embodiment of the present disclosure. FIG. 7 is a structural diagram of a display panel in accordance with a sixth preferred embodiment of the present disclosure. The dividing line between the first pixel units and the second pixel units in the display panel in accordance with the present disclosure may be at least one of a dividing line in a square wave shape, a dividing line in a sine wave shape, a dividing line in a triangle wave shape, a dividing line in a trapezoid wave shape, a dividing line in a sawtooth wave shape, and a dividing line in a step wave shape. The dividing line shown in FIG. 4 is the dividing line in the triangle wave shape. The dividing line shown in FIG. 5 is the dividing line in the trapezoid wave shape. The dividing line shown in FIG. 6 is the dividing line in the step wave shape. The dividing line shown in FIG. 7 is a dividing line of combining the dividing line in the triangle wave shape and the dividing line in the sine wave shape. A user can design a specific shape of the dividing line according to demand.

The present disclosure also provides a display device which includes a backlight module and a display panel. The display panel includes a display panel body, a first data line driving circuit and a second data line driving circuit which are positioned at two sides of the display panel body, a first scan line driving circuit and a second scan line driving circuit which are positioned at the other two sides of the display panel body, first pixel units which are driven by the first data line driving circuit, and second pixel units which are driven by the second data line driving circuit. A dividing line is formed between the first pixel units and the second pixel units. The dividing line is a non-straight line.

Preferably, the dividing line is a dividing line in a wave shape.

Preferably, the dividing line swings at two sides of a horizontal center line of the display panel.

Preferably, the dividing line is a dividing line in a square wave shape.

Preferably, a highest point and a lowest point of the dividing line in the square wave shape are respectively set at two sides of the horizontal center line of the display panel.

Preferably, a distance between the highest point of the dividing line in the square wave and the horizontal center line is approximately equal to a distance between the lowest point of the dividing line in the square wave and the horizontal center line.

Preferably, the dividing line is a dividing line in a sine wave shape.

Preferably, a highest point and a lowest point of the dividing line in the sine wave shape are respectively set at two sides of the horizontal center line of the display panel.

Preferably, a distance between the highest point of the dividing line in the sine wave and the horizontal center line is approximately equal to a distance between the lowest point of the dividing line in the sine wave and the horizontal center line.

Preferably, the dividing line includes at least one of a dividing line in a square wave shape, a dividing line in a sine wave shape, a dividing line in a triangle wave shape, a dividing line in a trapezoid wave shape, and a dividing line in a step wave shape.

A specific operating principle of the display device in accordance with the present disclosure is the same as or similar to corresponding descriptions of the above-mentioned display panel in accordance with the preferred embodiment. An embodiment can be referred to the corresponding descriptions of the above-mentioned display panel in accordance with the preferred embodiment.

In the display panel and the display device in accordance with the present disclosure, the dividing line which is a non-straight line is disposed between the first pixel units and the corresponding second pixel units, so as to eliminate the dark phenomenon between the first pixel units and the second pixel units, increase the display effect of the display panel, and solve the technical problem that the display effect is worse in a conventional display panel and a conventional display device.

As is understood by a person skilled in the art, the foregoing preferred embodiments of the present disclosure are illustrative rather than limiting of the present disclosure. It is intended that they cover various modifications and similar arrangements be included within the spirit and scope of the present disclosure, the scope of which should be accorded the broadest interpretation so as to encompass all such modifications and similar structures.

What is claimed is:

1. A display panel, comprising a display panel body, a first data line driving circuit and a second data line driving circuit positioned at two sides of the display panel body, first pixel units driven by the first data line driving circuit, and second pixel units driven by the second data line driving circuit;
wherein a dividing line is formed between the first pixel units and the second pixel units, and the dividing line is a non-straight line;
the dividing line includes at least one of a dividing line in a wave shape, a dividing line in a square wave shape, a dividing line in a sine wave shape, a dividing line in a triangle wave shape, a dividing line in a trapezoid wave shape, and a dividing line in a step wave shape, and the dividing line swings at two sides of a horizontal center line of the display panel.

2. A display panel, comprising a display panel body, a first data line driving circuit and a second data line driving circuit positioned at two sides of the display panel body, first pixel units driven by the first data line driving circuit, and second pixel units driven by the second data line driving circuit;
wherein a dividing line is formed between the first pixel units and the second pixel units, and the dividing line is a non-straight line.

3. The display panel of claim 2, wherein the dividing line is a dividing line in a wave shape, and the dividing line swings at two sides of a horizontal center line of the display panel.

4. The display panel of claim 3, wherein the dividing line is a dividing line in a square wave shape.

5. The display panel of claim 4, wherein a highest point and a lowest point of the dividing line in the square wave shape are respectively set at two sides of the horizontal center line of the display panel.

6. The display panel of claim 5, wherein a distance between the highest point of the dividing line in the square wave and the horizontal center line is approximately equal to a distance between the lowest point of the dividing line in the square wave and the horizontal center line.

7. The display panel of claim 3, wherein the dividing line is a dividing line in a sine wave shape.

8. The display panel of claim 7, wherein a highest point and a lowest point of the dividing line in the square wave shape are respectively set at the two sides of the horizontal center line of the display panel.

9. The display panel of claim 8, wherein a distance between the highest point of the dividing line in the sine wave and the horizontal center line is approximately equal to a distance between the lowest point of the dividing line in the sine wave and the horizontal center line.

10. The display panel of claim 2, wherein the dividing line includes at least one of a dividing line in a square wave shape, a dividing line in a sine wave shape, a dividing line in a triangle wave shape, a dividing line in a trapezoid wave shape, and a dividing line in a step wave shape.

11. A display device, comprising a display panel, the display panel comprising a display panel body, a first data line driving circuit and a second data line driving circuit positioned at two sides of the display panel body, first pixel units driven by the first data line driving circuit, and second pixel units driven by the second data line driving circuit;
wherein a dividing line is formed between the first pixel units and the second pixel units, and the dividing line is a non-straight line.

12. The display device of claim 11, wherein the dividing line is a dividing line in a wave shape, and the dividing line swings at two sides of a horizontal center line of the display panel.

13. The display device of claim 12, wherein the dividing line is a dividing line in a square wave shape.

14. The display device of claim 13, wherein a highest point and a lowest point of the dividing line in the square wave shape are respectively set at two sides of the horizontal center line of the display panel.

15. The display device of claim 14, wherein a distance between the highest point of the dividing line in the square wave and the horizontal center line is approximately equal to a distance between the lowest point of the dividing line in the square wave and the horizontal center line.

16. The display device of claim 12, wherein the dividing line is a dividing line in a sine wave shape.

17. The display device of claim 16, wherein a highest point and a lowest point of the dividing line in the square wave shape are respectively set at the two sides of the horizontal center line of the display panel.

18. The display device of claim 17, wherein a distance between the highest point of the dividing line in the sine wave and the horizontal center line is approximately equal to a distance between the lowest point of the dividing line in the sine wave and the horizontal center line.

19. The display device of claim 11, wherein the dividing line includes at least one of a dividing line in a square wave shape, a dividing line in a sine wave shape, a dividing line in a triangle wave shape, a dividing line in a trapezoid wave shape, and a dividing line in a step wave shape.
